(19) United States
(12) Patent Application Publication
(10) Pub. No.: US 2010/0320490 A1
(43) Pub. Date: Dec. 23, 2010

(54) LIGHT EMITTING DIODE PACKAGING STRUCTURE

(75) Inventors: Chun-Liang Lin, Tainan County (TW); Yan-Kun Su, Tainan City (TW)

Correspondence Address: WPAT, PC;INTELLECTUAL PROPERTY ATTORNEYS, 2030 MAIN STREET, SUITE 1300, IRVINE, CA, 92614, US

(73) Assignee: KUN SHAN UNIVERSITY, Tainan County (TW)

(21) Appl. No.: 12/631,244

(22) Filed: Dec. 4, 2009

(30) Foreign Application Priority Data
Jun. 23, 2009 (TW) 098121076

(51) Int. Cl. H01L 33/00

(52) U.S. Cl. 257/98; 257/99; 257/E33.056; 257/E33.067

(57) ABSTRACT

A light emitting diode (LED) packaging structure includes a base, a transparent layer, and an LED chip. The transparent layer is provided between the LED chip and the base to increase a relative distance between the LED chip and the base. With an increased relative distance between the LED chip and the base and the light transmitting function of the transparent layer, the overall LED packaging structure can have enhanced light extraction efficiency. Further, the transparent layer provides good thermal conductivity and accordingly, forms no harm to the heat dissipation efficiency of the LED.

### FIELD OF THE INVENTION

The present invention relates to a light emitting diode (LED) packaging structure, and more particularly to an LED packaging structure that enables enhanced light extraction efficiency of an LED chip.

### BACKGROUND OF THE INVENTION

Due to its advantages of small volume, low power consumption, and long service life, the conventional light emitting diode (LED) has gradually replaced the traditional bulbs and been widely applied in traffic signs, vehicle directional signals, flashlights, mobile phones, lamps, and large-scale outdoor signboards. Therefore, it is desirable to develop the techniques of enhancing the light extraction efficiency of LED to thereby further expand its application in different fields. In the conventional manner of packaging an LED, the substrate for the LED is thinned and the LED chip is bonded to a lead frame, a printed circuit board, a silicon substrate, or a metal substrate. Then, wire bonding to electrodes and encapsulating of LED chip are performed. Generally, the chip bonding layer has a relative small thickness. As a result, it is difficult to extract photons emitted toward the base. In the case the thickness of the chip bonding layer is increased, the problem with heat dissipation will occur due to the low thermal conductivity of the bonding layer. Therefore, most part of the incident light projected toward the substrate can not be efficiently extracted to adversely affect the light output efficiency of the LED.

FIG. 1 schematically shows a conventional LED packaging structure, in which an LED chip 13 is bonded to a lead frame 11 via a chip bonding layer 12, a wire is electrically bonded to each of a first electrode 131 and a second electrode 132 on the LED chip 13 through wire bonding, and the LED chip 13 is encapsulated to complete the LED packaging process. The lead frame 11 can be a printed circuit board, a silicon substrate, or a metal substrate. The LED chip 13 includes a light emitting layer 133, which emits a light source 14. Since the chip bonding layer 12 has a relative small thickness, the light source 14 emitted from the light emitting layer 133 and reflected by the lead frame 11 tends to be blocked by the LED chip 13 or be absorbed by the substrate of the LED 13, resulting in reduced brightness of the LED chip 13.

### SUMMARY OF THE INVENTION

A primary object of the present invention is to provide an LED packaging structure that enables enhanced light extraction efficiency of the LED packaging structure to solve the problem of poor light extraction efficiency as found in the conventional LED packaging structure.

Another object of the present invention is to provide an LED packaging structure that includes a base, a transparent layer, an LED chip, and a bonding layer. The transparent layer is provided atop the base, the LED chip is provided atop the transparent layer, and the bonding layer is provided between the transparent layer and the LED chip to bond the LED chip to the transparent layer.

A further object of the present invention is to provide an LED packaging structure that includes a metal substrate, a conductive transparent layer, an LED chip, and a bonding layer. The conductive transparent layer is provided atop the metal substrate, the LED chip is provided atop the conductive transparent layer, and the bonding layer is provided between the conductive transparent layer and the LED chip to bond the LED chip to the conductive transparent layer.

A still further object of the present invention is to provide an LED packaging structure that includes a base, a transparent layer, and an LED chip. The transparent layer is provided between the LED chip and the base to increase a relative distance between the LED chip and the base. With an increased relative distance between the LED chip and the base and the light transmitting function of the transparent layer, the probability for photons emitted toward the base to extract from side walls of the transparent layer is increased, which in turn enhances the light extraction efficiency of the overall LED packaging structure. Further, the transparent layer provides good thermal conductivity and accordingly, forms no harm to the heat dissipation efficiency of the LED chip.

The LED packaging structure according to the present invention provides one or more of the following advantages:

(1) The provision of the transparent layer in the LED packaging structure increases the relative distance between the LED chip and the base to thereby enhance the light extraction efficiency of the overall LED packaging structure.

(2) With the light transmitting property of the transparent layer provided in the LED packaging structure, photons emitted from the LED chip can pass through side walls of the transparent layer to thereby increase the brightness of the LED chip.

(3) With the good thermal conductivity of the transparent layer provided in the LED packaging structure, the increased relative distance between the LED chip and the base does not adversely affect the heat dissipation efficiency of the LED chip, so that the problems of shortened service life and reduced brightness of the LED due to overheat can be avoided.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic view showing a conventional LED packaging structure;

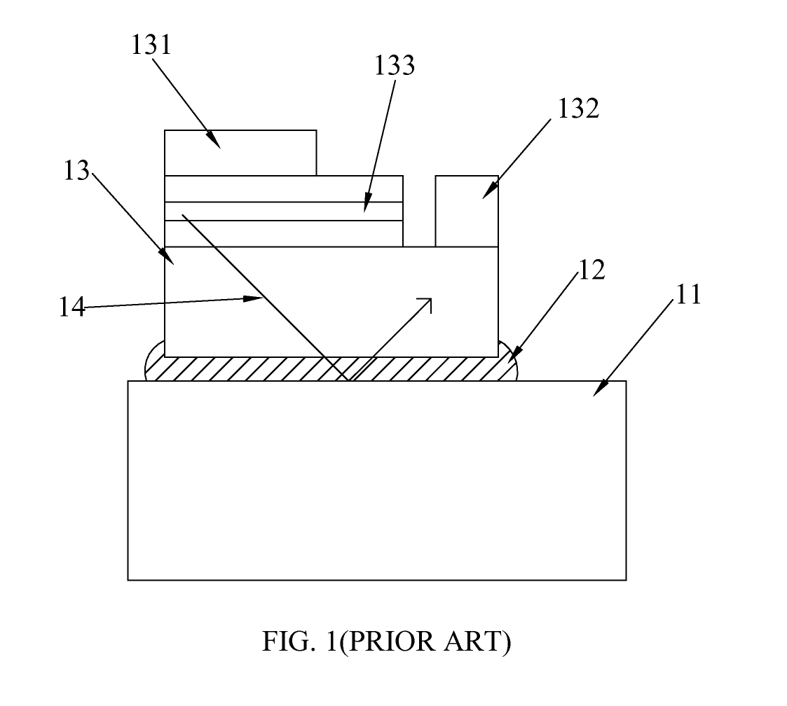

FIG. 2 is a schematic view showing an LED packaging structure according to a first embodiment of the present invention;

FIG. 3 is a schematic view showing an LED packaging structure according to a second embodiment of the present invention;

FIG. 4 is a schematic view showing an LED packaging structure according to a third embodiment of the present invention;

FIG. 5 is a schematic view showing an LED packaging structure according to a fourth embodiment of the present invention;

FIG. 6 is a schematic view showing a first structure for the transparent layer of the LED packaging structure of the present invention; and

FIG. 7 is a schematic view showing a second structure for the transparent layer of the LED packaging structure of the present invention.

### DETAILED DESCRIPTION OF THE PREFERRED EMBODIMENTS

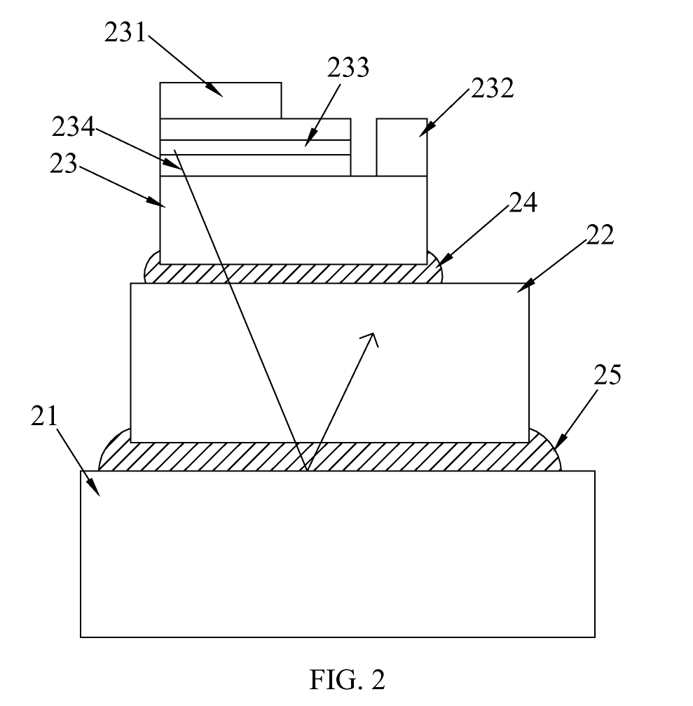

Please refer to FIG. 2 that is a schematic view showing a light emitting diode (LED) packaging structure according to a first embodiment of the present invention. As shown, the LED packaging structure in the first embodiment includes a base 21, a transparent layer 22, an LED chip 23, and a bonding layer 24. The transparent layer 22 is provided atop the base 21, the LED chip 23 is provided atop the transparent layer 22, and the bonding layer 24 is applied between the transparent layer 22 and the LED chip 23 to bond the LED chip 23 to the transparent layer 22.

A first electrode 231 and a second electrode 232 are provided on the top of the LED chip 23. Then, wire bonding is performed for the first electrode 231 and the second electrode 232, so that a wire (not shown) is bonded to each of the first and the second electrode 231, 232 for inputting electric current thereto.

Then, the LED chip 23 is encapsulated to complete the packaging process. An adhesive compound 25 is further applied between the transparent layer 22 and the base 21 to bond the transparent layer 22 to the base 21. It is noted the transparent layer 22 can be otherwise directly deposited on the base 21 or directly coated on the base 21 instead of being bonded to the base 21 using the adhesive compound 25. Therefore, in the present invention, the transparent layer 22 can be connected to the base 21 in a manner as suggested in the first embodiment without being limited thereto.

The transparent layer 22 can be deposited in a predetermined area on the base 21 through standard exposure and development process, local deposition process, etc. Preferably, the base 21 is a lead frame, a printed circuit board (PCB), a silicon substrate, a transparent substrate or a metal substrate, and can be made of a metal material, a semiconductor material, a ceramic material, a plastic material or a glass material.

The LED chip 23 has a light emitting layer 233, which emits a light source 234. By providing the transparent layer 22, a relative distance between the LED chip 23 and the base 21 is increased. As a result, the light source 234 reflected by the base 21 can be transmitted to external environment more easily. Further, the transparent layer 22 is formed using a light transmitting material containing zinc oxide (ZnO), including but not limited to zinc oxide (ZnO), indium zinc oxide (InZnO), gallium zinc oxide (GaZnO), and aluminum zinc oxide (AlZnO). The transparent layer 22 can be a single-layer structure or a multi-layer structure, and has good transmittance of light to enable enhanced light extraction efficiency of the LED chip 23.

Further, the transparent layer 22 containing ZnO provides good thermal conductivity, which in turn allows degree of freedom in increasing the relative distance between the LED chip 23 and the base 21. Therefore, the LED chip 23 is not subject to the drawback of reduced brightness or shortened service life due to any increase in the relative distance between it and the base 21. It is also noted the thickness of the transparent layer 22 corresponds to the wavelength of the light source 234. Thus, the thickness of the transparent layer 22 can be adjusted according to the wavelength of the light source 234.

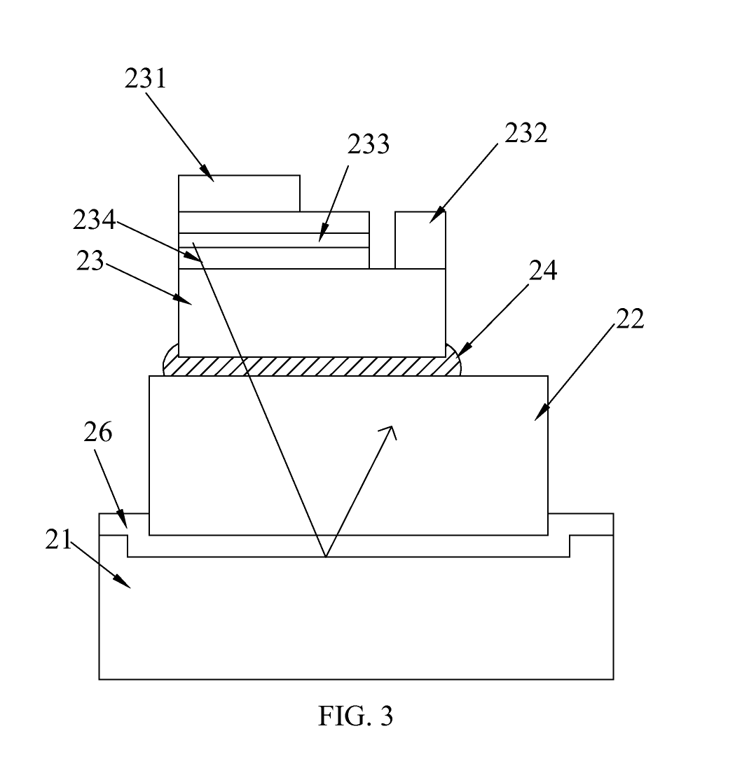

Please refer to FIG. 3, which is a schematic view showing an LED packaging structure according to a second embodiment of the present invention. As shown, the LED packaging structure in the second embodiment includes a base 21, a transparent layer 22, an LED chip 23, and a bonding layer 24. The transparent layer 22 is provided atop the base 21, the LED chip 23 is provided atop the transparent layer 22, and the bonding layer 24 is applied between the transparent layer 22 and the LED chip 23 to bond the LED chip 23 to the top of the transparent layer 22. A first electrode 231 and a second electrode 232 are provided on the top of the LED chip 23. Then, wire bonding is performed for the first electrode 231 and the second electrode 232, so that a wire is bonded to each of the first and the second electrode 231, 232 for inputting electric current thereto. Then, the LED chip 23 is encapsulated to complete the packaging process. The base 21 can be electroplated on one side of the transparent layer 22 directly, or by depositing a thin metal layer on the side of the transparent layer 22 first and then electroplating the base 21 on the transparent layer 22. The LED chip 23 is then bonded to another side of the transparent layer 22 opposite to the base 21. Thereafter, wire bonding is performed for the first and the second electrode 231, 232, and the LED chip 23 is encapsulated. The transparent layer 22 is inlayed into the base 21.

A reflective layer 26 can be further formed between the transparent layer 22 and the base 21. The reflective layer 26 can be of a distributed Bragg reflector (DBR), which reflects the light source emitted from the LED chip 23. Further, the reflective layer 26 can be a single-metal material or a multi-metal material, or be a multi-layer dielectric material to enhance its reflectivity of the light source 234 and the light extraction efficiency of the overall LED packaging structure.

The base 21 is a lead frame, a printed circuit board (PCB), a silicon substrate, a transparent substrate or a metal substrate, and can be made of a metal material, a semiconductor material, a ceramic material, a plastic material or a glass material. The transparent layer 22 is formed using a light transmitting material containing zinc oxide (ZnO), including but not limited to zinc oxide (ZnO), indium zinc oxide (InZnO), gallium zinc oxide (GaZnO), and aluminum zinc oxide (AlZnO).

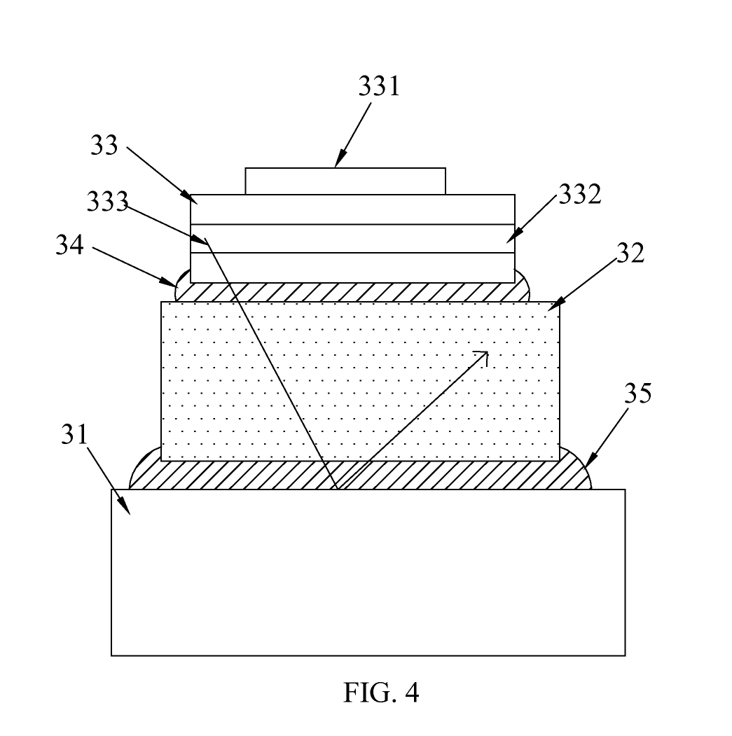

FIG. 4 is a schematic view showing an LED packaging structure according to a third embodiment of the present invention. As shown, the LED packaging structure in the third embodiment includes a metal substrate 31, a conductive transparent layer 32, an LED chip 33, and a conductive bonding layer 34. The conductive transparent layer 32 is provided atop the metal substrate 31, the LED chip 33 is provided atop the conductive transparent layer 32, and the conductive bonding layer 34 is applied between the conductive transparent layer 32 and the LED chip 33 to bond the LED chip 33 to the top of the conductive transparent layer 32. A first electrode 331 is provided on the top of the LED chip 33, and a wire (not shown) is bonded to the first electrode 331 for inputting electric current thereto. An adhesive compound 35 is further applied between the conductive transparent layer 32 and the metal substrate 31 to bond the conductive transparent layer 32 to the metal substrate 31. It is noted the conductive transparent layer 32 can be otherwise directly deposited on the metal substrate 31 or directly coated on the metal substrate 31 instead of being bonded to the metal substrate 31 using the adhesive compound 35. Therefore, in the present invention, the conductive transparent layer 32 can be connected to the metal substrate 31 in a manner as suggested in the third embodiment without being limited thereto.

The conductive transparent layer 32 can be deposited in a predetermined area on the metal substrate 31 through standard exposure and development process, local deposition process, etc. The conductive transparent layer 32 is formed using a light transmitting material containing zinc oxide (ZnO), including but not limited to zinc oxide (ZnO), indium zinc oxide (InZnO), gallium zinc oxide (GaZnO), and aluminum zinc oxide (AlZnO). The conductive transparent layer 32 can be further doped with aluminum (Al) or gallium (Ga) to thereby have good electric conductivity. The metal substrate 31 can be made of nickel (Ni), copper (Cu), or alloys of nickel and/or copper.

The LED chip 33 has a light emitting layer 332, which emits a light source 333. By providing the conductive transparent layer 32, a relative distance between the LED chip 33 and the metal substrate 31 can be increased. As a result, the light source 333 reflected by the metal substrate 31 can be transmitted to external environment more easily. The conductive transparent layer 32 has good transmittance of light to enable enhanced light extraction efficiency of the LED chip 33.

Further, the conductive transparent layer 32 containing ZnO provides good thermal conductivity, which in turn allows degree of freedom in increasing the relative distance between the LED chip 33 and the metal substrate 31. Therefore, the LED chip 33 is not subject to the drawback of reduced brightness or shortened service life caused by exceeded temperature due to any increase in the relative distance between it and the metal substrate 31. It is also noted the thickness of the conductive transparent layer 32 corresponds to the wavelength of the light source 333. Thus, the thickness of the conductive transparent layer 32 can be adjusted according to the wavelength of the light source 333.

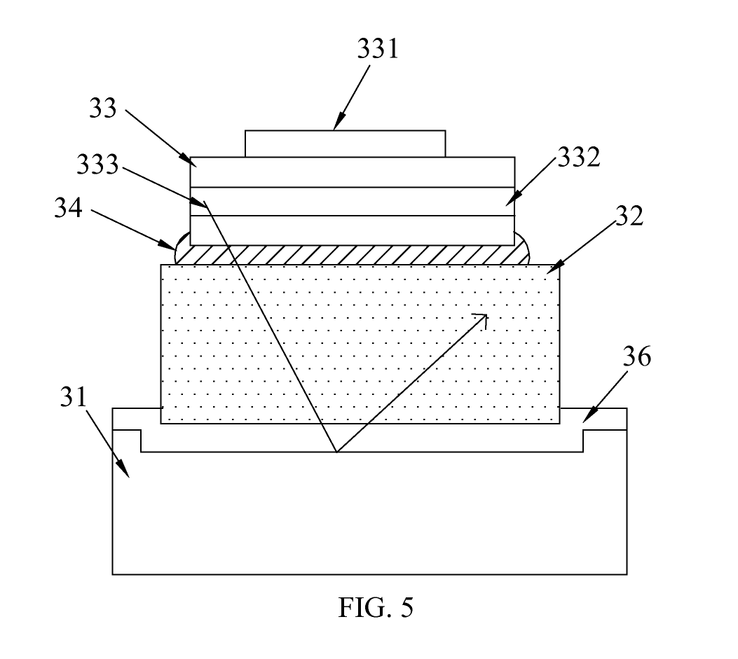

FIG. 5 is a schematic view showing an LED packaging structure according to a fourth embodiment of the present invention. As shown, the LED packaging structure in the fourth embodiment includes a metal substrate 31, a conductive transparent layer 32, an LED chip 33, and a conductive bonding layer 34. The conductive transparent layer 32 is provided atop the metal substrate 31, the LED chip 33 is provided atop the conductive transparent layer 32, and the conductive bonding layer 34 is applied between the conductive transparent layer 32 and the LED chip 33 to bond the LED chip 33 to the top of the conductive transparent layer 32. A first electrode 331 is provided on the top of the LED chip 33, and a wire (not shown) is bonded to the first electrode 331 for inputting electric current thereto. The metal substrate 31 can be electroplated on one side of the conductive transparent layer 32 directly, or by depositing a thin metal layer on the side of the conductive transparent layer 32 first and then electroplating the metal substrate 31 on the conductive transparent layer 32. The LED chip 33 is then bonded to another side of the conductive transparent layer 32 opposite to the metal substrate 31. Thereafter, wire bonding is performed for the first electrode 331, and the LED chip 33 is encapsulated. The conductive transparent layer 32 is inlayed into the metal substrate 31.

The conductive transparent layer 32 is formed using a light transmitting material containing zinc oxide (ZnO), including but not limited to zinc oxide (ZnO), indium zinc oxide (InZnO), gallium zinc oxide (GaZnO), and aluminum zinc oxide (AlZnO). The conductive transparent layer 32 can be further doped with aluminum (Al) or gallium (Ga) to thereby have good electric conductivity. The metal substrate 31 can be made of nickel (Ni), copper (Cu), or alloys of nickel and/or copper. The metal substrate 31 is a lead frame, a printed circuit board (PCB), a silicon substrate, a transparent substrate or a metal substrate, and can be made of a metal material, a semiconductor material, a ceramic material, a plastic material or a glass material. A reflective layer 36 can be further formed between the conductive transparent layer 32 and the metal substrate 31. The reflective layer 36 can be of a distributed Bragg reflector (DBR), which reflects the light source emitted from the LED chip 33. Further, the reflective layer 36 can be a single-metal material or a multi-metal material, or be a multi-layer dielectric material to enhance its reflectivity of the light source 333 and the light extraction efficiency of the overall LED packaging structure.

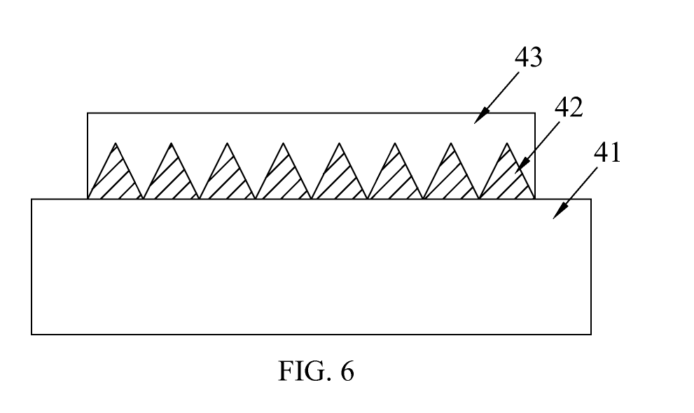

Please refer to FIG. 6 that shows a first structure for the transparent layer of the LED packaging structure of the present invention. As shown, a transparent layer 43 with the first structure is formed atop a base 41, and an adhesive compound 42 can be used between the transparent layer 43 and the base 41 to firmly bond them to each other. According to the first structure, one or both of two opposite faces of the transparent layer 43 are roughed to enhance the light extraction efficiency of the LED packaging structure of the present invention. The base 41 can be a lead frame, a printed circuit board (PCB), a silicon substrate, a transparent substrate or a metal substrate. It is noted the transparent layer 43 can doped with aluminum (Al) or gallium (Ga) to thereby become electrically conductive. The adhesive compound 42 can also be electrically conductive.

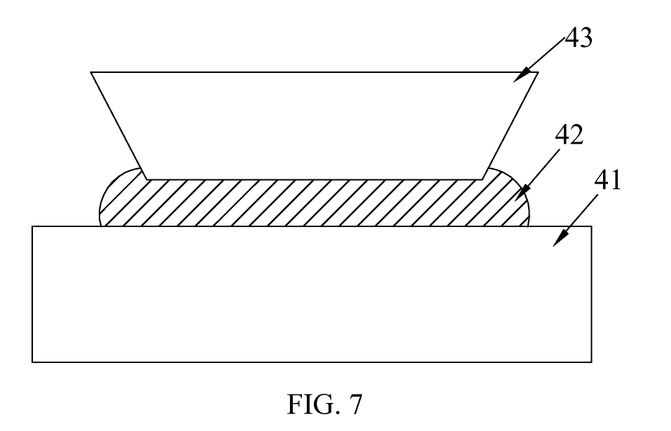

FIG. 7 shows a second structure for the transparent layer of the LED packaging structure of the present invention. As shown, a transparent layer 43 with the second structure is formed atop a base 41, and an adhesive compound 42 can be used between the transparent layer 43 and the base 41 to firmly bond them to each other. According to the second structure, side walls of the transparent layer 43 are formed into beveled surfaces, so that more parts of the light source can be reflected out to the external environment to enhance the light extraction efficiency of the LED packaging structure of the present invention. The base 41 can be a lead frame, a printed circuit board (PCB), a silicon substrate, a transparent substrate or a metal substrate. It is noted the transparent layer 43 can doped with aluminum (Al) or gallium (Ga) to thereby become electrically conductive. The adhesive compound 42 can also be electrically conductive.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A light emitting diode (LED) packaging structure, comprising:
a base;
a transparent layer being provided atop the base;
an LED chip being provided atop the transparent layer; and
a bonding layer being applied between the transparent layer and the LED chip to bond the LED chip to the transparent layer.

2. The LED packaging structure as claimed in claim 1, wherein the LED chip is provided on a top with a first electrode and a second electrode.

3. The LED packaging structure as claimed in claim 2, wherein the first electrode and the second electrode are respectively bonded to a wire for inputting electric current thereto.

4. The LED packaging structure as claimed in claim 1, further comprising an adhesive compound applied between the transparent layer and the base to thereby bond the transparent layer to the base.

5. The LED packaging structure as claimed in claim 1, wherein the transparent layer is provided on the base through deposition.

6. The LED packaging structure as claimed in claim 1, wherein the transparent layer is led into the base.

7. The LED packaging structure as claimed in claim 1, wherein the transparent layer is selected from the group consisting of a single-layer structure and a multi-layer structure.

8. The LED packaging structure as claimed in claim 1, wherein the transparent layer is formed using a light transmitting material containing zinc oxide (ZnO).

9. The LED packaging structure as claimed in claim 1, further comprising a reflective layer provided between the transparent layer and the base.

10. The LED packaging structure as claimed in claim 9, wherein the reflective layer is of a distributed Bragg reflector (DBR), which reflects a light source emitted from the LED chip.

11. The LED packaging structure as claimed in claim 1, wherein the transparent layer has at least one beveled side wall.

12. The LED packaging structure as claimed in claim 1, wherein at least one of two opposite sides of the transparent layer is roughed.

13. An LED packaging structure, comprising:
a metal substrate;
a conductive transparent layer being provided atop the metal substrate;
an LED chip being provided atop the conductive transparent layer; and
a conductive bonding layer being applied between the conductive transparent layer and the LED chip to bond the LED chip to the conductive transparent layer.

14. The LED packaging structure as claimed in claim 13, wherein the LED chip is provided on a top with a first electrode.

15. The LED packaging structure as claimed in claim 14, wherein the first electrode is bonded to a wire for inputting electric current thereto.

16. The LED packaging structure as claimed in claim 13, further comprising an adhesive compound applied between the conductive transparent layer and the metal substrate to thereby bond the conductive transparent layer to the metal substrate.

17. The LED packaging structure as claimed in claim 13, wherein the conductive transparent layer is led into the metal substrate.

18. The LED packaging structure as claimed in claim 13, wherein the conductive transparent layer is selected from the group consisting of a single-layer structure and a multi-layer structure.

19. The LED packaging structure as claimed in claim 13, wherein the conductive transparent layer is formed using a light transmitting material containing zinc oxide (ZnO).

20. The LED packaging structure as claimed in claim 13, further comprising a reflective layer provided between the conductive transparent layer and the metal substrate.

21. The LED packaging structure as claimed in claim 20, wherein the reflective layer is of a distributed Bragg reflector (DBR), which reflects a light source emitted from the LED chip.

22. The LED packaging structure as claimed in claim 13, wherein the conductive transparent layer has at least one beveled side wall.

23. The LED packaging structure as claimed in claim 13, wherein at least one of two opposite sides of the conductive transparent layer is roughed.

24. The LED packaging structure as claimed in claim 13, wherein the metal substrate is selected from the group consisting of a single-metal structure and a multi-metal structure.

25. The LED packaging structure as claimed in claim 13, wherein the metal substrate is made of a metal material selected from the group consisting of nickel (Ni) and copper (Cu).
